(19) United States
(12) Patent Application Publication
(10) Pub. No.: US 2010/0036623 A1
(43) Pub. Date: Feb. 11, 2010

(54) ELECTRICITY DETECTING SYSTEM AND METHOD HAVING A VERIFYING MECHANISM FOR VERIFYING MEASURED ELECTRICITY VALUES

(76) Inventors: Ren-Chyuan LUO, Taipei (TW); Kuo-Lan SU, Chiayi County (TW); Jyh-Hwa TZOU, Chiayi County (TW)

Correspondence Address: OSTROLENK FABER GERB & SOFFEN, 1180 AVENUE OF THE AMERICAS, NEW YORK, NY, 100368403, US

(21) Appl. No.: 12/535,758

(22) Filed: Aug. 5, 2009

(30) Foreign Application Priority Data
Aug. 6, 2008 (TW) 097129812

(51) Int. Cl. G06F 19/00; G01R 21/06

(52) U.S. Cl. 702/60; 702/57

(57) ABSTRACT

An electricity detecting system includes a detector module operable to generate a plurality of source electricity values of a target electricity value, and a computing unit coupled to the detector module and receiving the source electricity values therefrom. The detector module includes a plurality of detectors, and each of the source electricity values is obtained using a respective one of the detectors. The computing unit is configured to determine weight values corresponding to the source electricity values while taking into account accuracy of the latter, and to determine a verified electricity value corresponding to the target electricity value from the source electricity values and their weight values. The computing unit is further configured to exclude the source electricity values corresponding to the detectors that have experienced breakdown from determination of the verified electricity value.

### CROSS-REFERENCE TO RELATED APPLICATION

This application claims priority of Taiwanese Application No. 097129812, filed on Aug. 6, 2008.

### BACKGROUND OF THE INVENTION

1. Field of the Invention

The present invention relates to an electricity detecting system and method, more particularly to an electricity detecting system and method having a verifying mechanism for verifying measured electricity values.

2. Description of the Related Art

A conventional electricity detecting device directly shows a measured electricity value after detecting a target electricity value. However, the measured electricity value is not always reliable since the measured electricity value did not undergo verification processing. Moreover, the measured electricity value may be wrong due to a breakdown of a detector of the electricity detecting device.

### SUMMARY OF THE INVENTION

Therefore, an object of the present invention is to provide an electricity detecting method capable of increasing reliability and accuracy.

Accordingly, an electricity detecting method of the present invention comprises:

a) receiving a plurality of source electricity values of a target electricity value, each of the source electricity values being obtained using a respective detector;

b) determining a threshold value and a weight value for each of the source electricity values;

c) selecting one of the source electricity values as a to-be-verified value;

d) selecting another one of the source electricity values as a to-be-compared value;

e) adding a predetermined value to the weight value of the to-be-verified value when an absolute value of a difference between the to-be-verified value and the to-be-compared value is smaller than an absolute value of a sum of the threshold values of the to-be-verified value and the to-be-compared value;

f) repeating step e) using yet another one of the source electricity values as the to-be-compared value until all of the source electricity values other than that selected as the to-be-verified value in step c) have been selected as the to-be-compared value;

g) repeating steps d) to f) using another one of the source electricity values as the to-be-verified value until all of the source electricity values have been selected as the to-be-verified value; and

h) determining a verified electricity value corresponding to the target electricity value based upon a quotient of a summation of products of each of the source electricity values and the weight value corresponding thereto, and a summation of the weight values of the source electricity values.

Another object of the present invention is to provide an electricity detecting system capable of increasing reliability and accuracy.

According to another aspect of this invention, an electricity detecting system comprises a detector module operable to generate a plurality of source electricity values of a target electricity value, and a computing unit coupled to the detector module and receiving the source electricity values therefrom. The detector module includes a plurality of detectors, and each of the source electricity values is obtained using a respective one of the detectors. The computing unit is configured to perform a method including the steps of:

a) determining a threshold value and a weight value for each of the source electricity values;

b) selecting one of the source electricity values as a to-be-verified value;

c) selecting another one of the source electricity values as a to-be-compared value;

d) adding a predetermined value to the weight value of the to-be-verified value when an absolute value of a difference between the to-be-verified value and the to-be-compared value is smaller than an absolute value of a sum of the threshold values of the to-be-verified value and the to-be-compared value;

e) repeating step d) using yet another one of the source electricity values as the to-be-compared value until all of the source electricity values other than that selected as the to-be-verified value in step b) have been selected as the to-be-compared value;

f) repeating steps c) to e) using another one of the source electricity values as the to-be-verified value until all of the source electricity values have been selected as the to-be-verified value; and

g) determining a verified electricity value corresponding to the target electricity value based upon a quotient of a summation of products of each of the source electricity values and the weight value corresponding thereto, and a summation of the weight values of the source electricity values.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic block diagram of the preferred embodiment of an electricity detecting system of this invention;

FIG. 2 is a flow chart of the preferred embodiment of an electricity detecting method of this invention;

FIG. 3 is a plot showing illustrative measured electricity values, each obtained using a respective detector in a normal state of the electricity detecting system of the preferred embodiment;

FIG. 4 is a plot showing an average of the measured electricity values in FIG. 3 and a verified electricity value obtained using the electricity detecting method of this invention;

FIG. 5 is a plot similar to FIG. 3 but showing the measured electricity values obtained when first and fourth detectors have experienced breakdown;

FIG. 6 is a plot showing an average of the measured electricity values in FIG. 5 and a verified electricity value obtained using the electricity detecting method of this invention;

FIG. 7 is a plot similar to FIG. 3 but showing the measured electricity values obtained when a pair of the detectors have experienced breakdown and generate similar measured electricity values;

FIG. 8 is a plot showing an average of the measured electricity values in FIG. 7 and a verified electricity value obtained using the electricity detecting method of this invention;

FIG. 9 is a plot similar to FIG. 3 but showing the measured electricity values having large differences from each other; and

FIG. 10 is a plot showing an average of the measured electricity values in FIG. 9 and a verified electricity value obtained using the electricity detecting method of this invention.

### DETAILED DESCRIPTION OF THE PREFERRED EMBODIMENT

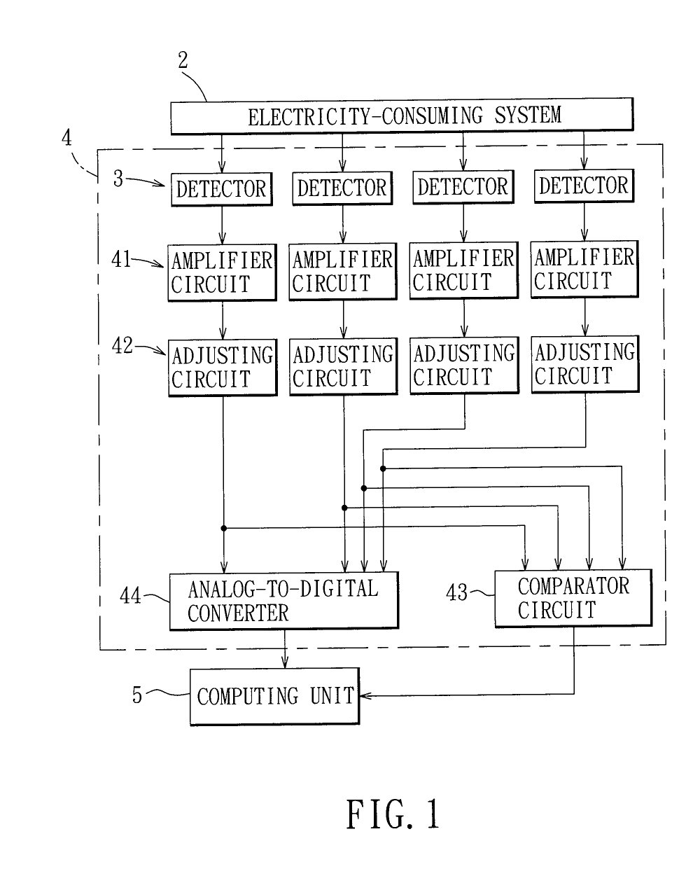

Referring to FIG. 1, the preferred embodiment of an electricity detecting system of the present invention is adapted for detecting a target electricity value of an electricity-consuming system 2. The electricity detecting system includes a detector module 4 operable to generate a plurality of source electricity values according to the target electricity value, and a computing unit 5 coupled to the detector module 4 and receiving the source electricity values therefrom for determining a verified electricity value corresponding to the target electricity value. In this embodiment, the computing unit 5 is a single-chip microprocessor, such as an 89C51 microcontroller.

The detector module 4 includes a plurality of detectors 3, and each of the detectors 3 outputs a measuring electrical signal from which the corresponding source electricity value is obtained. In this embodiment, the detector module 4 includes four detectors 3, and each of the detectors 3 is, but not limited to, a current detector. In other embodiments, each of the detectors 3 could be a voltage detector.

The detector module 4 further includes a plurality of amplifier circuits 41, a plurality of adjusting circuits 42, a comparator circuit 43, and an analog-to-digital converter 44. The amplifier circuits 41 are coupled respectively to the detectors 3 for amplifying the measuring electrical signals to result in amplified electrical signals, respectively. The adjusting circuits 42 are coupled respectively to the amplifier circuits 41 for adjusting levels of the amplified electrical signals to result in adjusted voltage signals, respectively. Particularly, each of the adjusted voltage signals ranges from 0V to 5V. The analog-to-digital converter 44 is coupled to the adjusting circuits 42 for converting each of the adjusted voltage signals into digital form to result in the corresponding source electricity value (I₁˜I₄). The comparator circuit 43 is coupled to the adjusting circuits 42 and the computing unit 5 for indicating to the computing unit 5 the source electricity value that exceeds a predetermined safety reference value set by an operator beforehand. The computing unit 5 is configured to exclude the source electricity value that exceeds the predetermined safety reference value from determination of the verified electricity value.

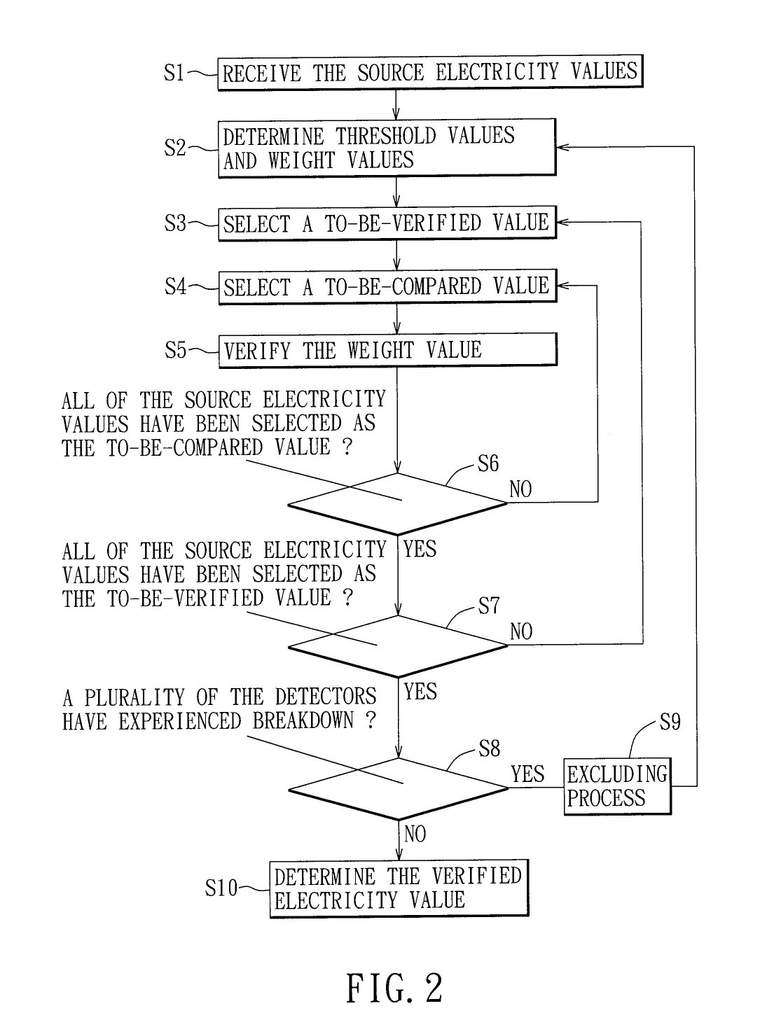

Referring to FIG. 2, the computing unit 5 is further configured to perform an electricity detecting method for verifying the source electricity values. The electricity detecting method is a redundancy management method for increasing reliability and accuracy, and includes the following steps.

The computing unit 5 receives the source electricity values (I₁˜I₄) in step (S1), and is operable to determine a threshold value (B₁˜B₄) and a weight value (W₀˜W₄) for each of the source electricity values in step (S2). In this embodiment, each weight value determined in step (S2) has an initial value of 0, and each threshold value ranges from 5% to 10% of the source electricity value.

Then, the computing unit 5 is operable to select one of the source electricity values as a to-be-verified value (I₁) in step (S3), and to select another one of the source electricity values as a to-be-compared value (Iⱼ) in step (S4).

In step (S5), a difference between the to-be-verified value (Iᵢ) and the to-be-compared value (Iⱼ), and a sum of the threshold value (Bᵢ) of the to-be-verified value (Iᵢ) and the threshold value (Bⱼ) of the to-be-compared value (Iⱼ) are computed. The computing unit 5 adds a predetermined value (X) to the weight value (Wᵢ) of the to-be-verified value (Iᵢ) when an absolute value of the difference (Iᵢ−Iⱼ) is smaller than an absolute value of the sum (Bᵢ+Bⱼ), that is,

Wᵢ=Wᵢ+X if |Iᵢ−Iⱼ|≦|Bᵢ+Bⱼ|,

where i is an integer ranging from 1 to 4, j is another integer ranging from 1 to 4, and X is a fixed value.

In step (S6), the computing unit 5 is operable to determine whether all of the source electricity values other than that selected as the to-be-verified value in step (S3) have been selected as the to-be-compared value. The flow goes back to step (S4) to select yet another one of the source electricity values as the to-be-compared value if the determination is negative. Otherwise, the computing unit 5 proceeds to step (S7) if all of the source electricity values other than that selected as the to-be-verified value in step (S3) have been selected as the to-be-compared value.

In step (S7), the computing unit 5 is operable to determine whether all of the source electricity values have been selected as the to-be-verified value. The flow goes back to step (S3) to select another one of the source electricity values as the to-be-verified value if the determination is negative. Otherwise, the computing unit 5 proceeds to step (S8) if all of the source electricity values have been selected as the to-be-verified value.

Step (S8) is implemented for determining from the weight values if at least two of the detectors 3 corresponding to at least two of the source electricity values have experienced breakdown. The computing unit 5 proceeds to step (S9) for excluding the source electricity values and the weight values corresponding to the detectors 3 that have experienced breakdown if the determination is affirmative, and proceeds to step (S10) to determine the verified electricity value if otherwise.

In step (S9), the computing unit 5 computes an average of previously determined verified electricity values, and then computes a difference between each of the source electricity values and the average. For each of the source electricity values whose difference with the average is greater than the threshold value thereof, the computing unit 5 is configured to determine that the detector 3 corresponding thereto has experienced breakdown. Subsequently, the flow goes back to step (S2) while excluding the source electricity values and the weight values corresponding to the detectors 3 that have experienced breakdown. Further, the electricity detecting system can be configured to notify the operator as to which ones of the detectors 3 have broken down.

In step (S10), the computing unit 5 determines the verified electricity value (I) corresponding to the target electricity value based upon the source electricity values that were not excluded due to exceeding the predetermined safety reference value or due to their being obtained using faulty detectors 3, and the weight values corresponding to the non-excluded source electricity values. The computing unit 5 computes a summation of products of each of the non-excluded source electricity values and the weight value corresponding thereto, and a summation of the weight values of the non-excluded source electricity values. Then, the verified electricity value (I) is obtained based upon a quotient of the summation of the products and the summation of the weight values, i.e.,

$$I = {\sum }_{i = 1}^{4} ( {I}_{i} {W}_{i} ) / {\sum }_{i = 4}^{4} {W}_{i} .$$

The verified electricity value is outputted via a wired or wireless interface, or is shown to the operator via a liquid crystal display screen. It should be understood that this invention is not limited to the disclosed means for outputting the verified electricity value.

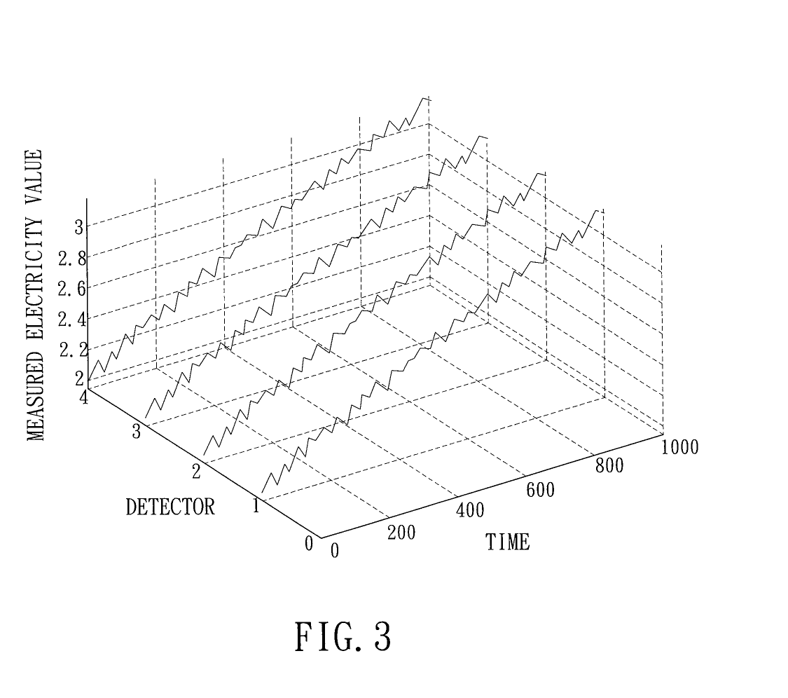

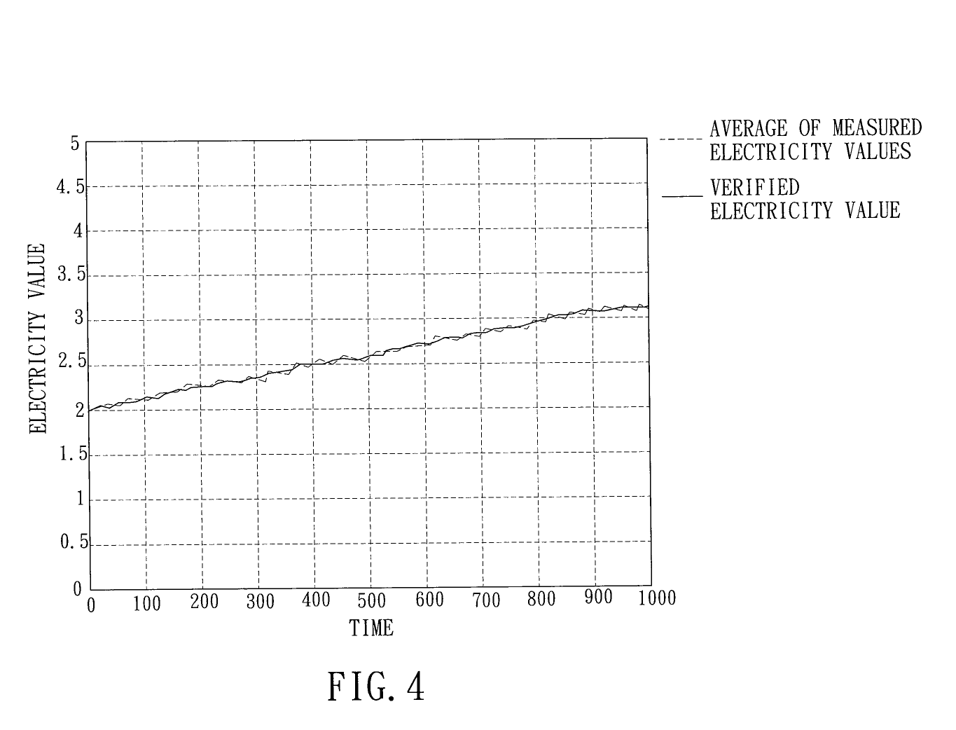

Further referring to FIGS. 3 and 4, when all of the detectors 3 are in the normal state and generate the measuring electrical signals indicating similar measured electricity values, the verified electricity value is similar to an average of the measured electricity values.

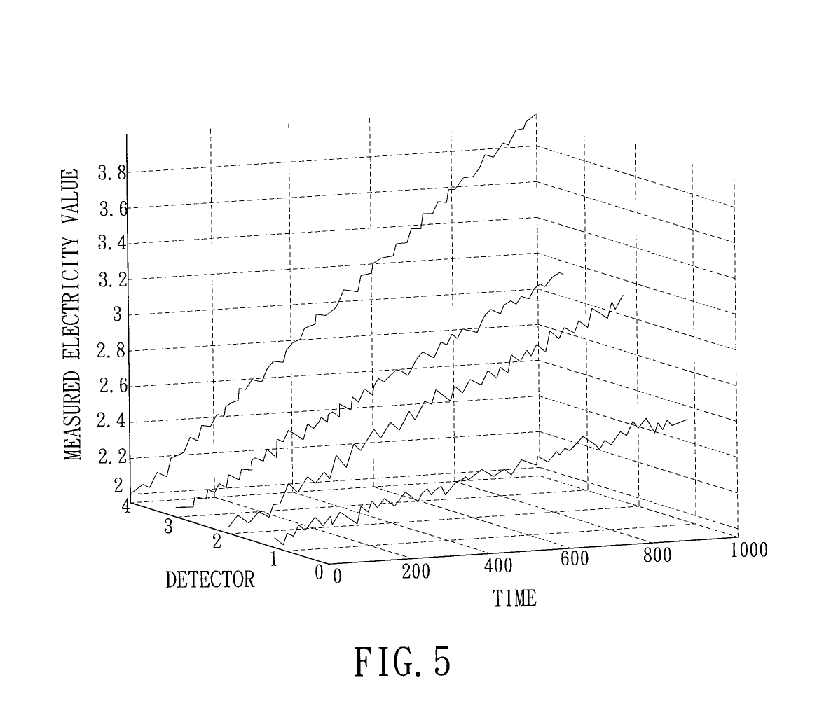

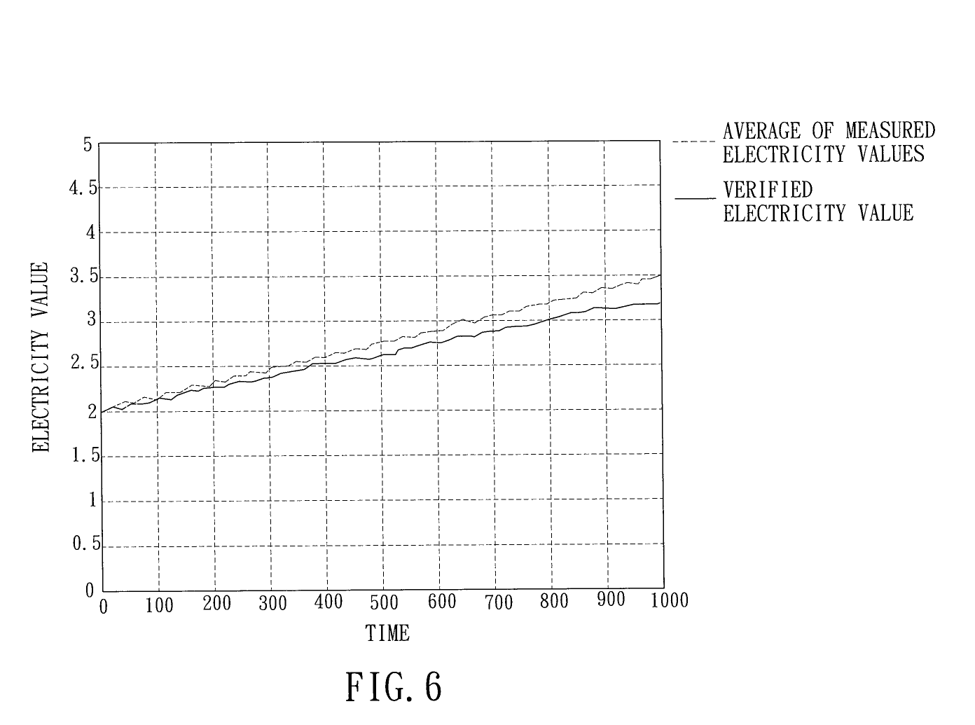

Referring to FIGS. 2, 5 and 6, when two (the first and fourth ones) of the detectors 3 have both experienced breakdown, there is a relatively large error in the measured electricity values corresponding to these two detectors 3 such that an average of the measured electricity values becomes relatively high. However, the weight values of the source electricity values corresponding to the first and fourth detectors 3 are both equal to C after step (S5) Due to the weight values obtained through step (S5), these two source electricity values are excluded from determination of the verified electricity value such that the verified electricity value determined in step (S10) is not affected thereby.

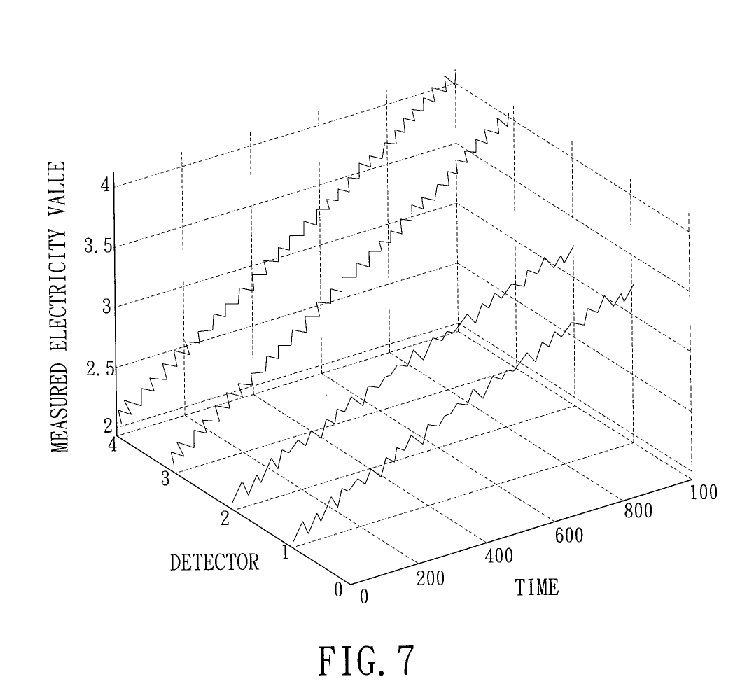

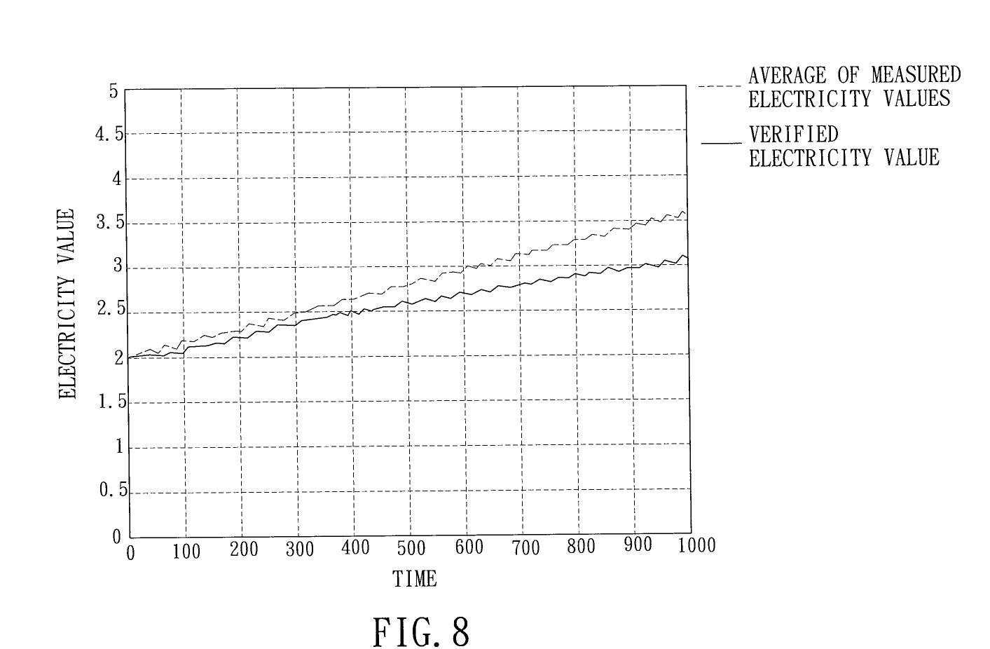

The following description is provided to explain step (S8) in more detail. Referring to FIGS. 2, 7 and 8, when two (the third and fourth ones) of the detectors 3 have experienced breakdown, and the measured electricity values corresponding to these two detectors 3 are similar, all of the weight values are non-zero and less than a product of one-half of a total number of the detectors and the predetermined value (X=1) added in step (S5). That is to say, all of the weight values are greater than 0 and less than 2 in this embodiment. In this case, the computing unit 5 is configured to make the determination in step (S8) as affirmative, and proceeds to step (S9) for excluding the source electricity values corresponding to the third and fourth detectors 3.

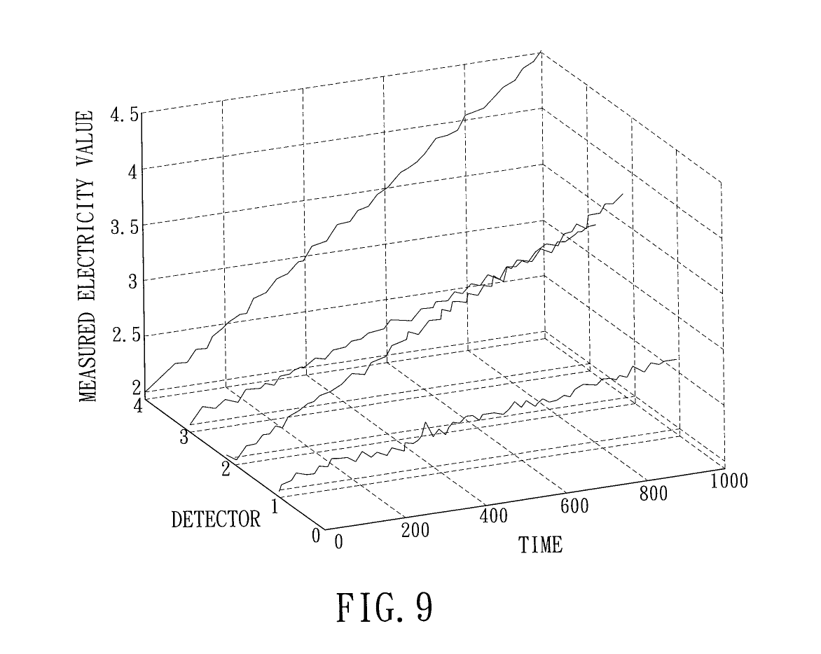

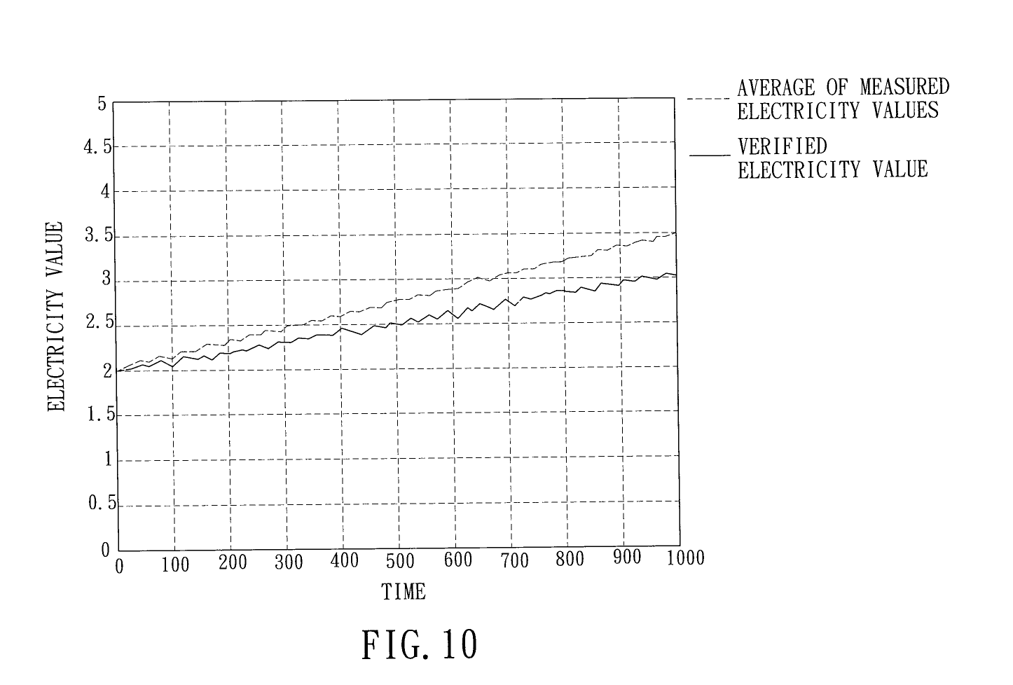

Referring to FIGS. 2, 9 and 10, when three (the first, second and fourth) of the detectors 3 have experienced breakdown, and all of the measured electricity values have large differences from each other, each of the weight values is equal to the initial value thereof, i.e., all of the weight values are equal to 0 in this embodiment. In this case, the computing unit 5 is configured to make the determination in step (S8) as affirmative, and proceeds to step (S9) for excluding the source electricity values corresponding to the first, second and fourth detectors 3.

The computing unit 5 can be configured or programmed to determine the above-mentioned cases or even other cases. Since programming of the computing unit 5 is not the object of this invention, details thereof will be omitted herein for the sake of brevity.

In sum, the electricity detecting system of this invention is capable of determining weight values corresponding to the source electricity values while taking into account accuracy of the latter. Moreover, the electricity detecting system is capable of excluding the source electricity values corresponding to the faulty detectors. Therefore, the verified electricity value is relatively accurate and reliable.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An electricity detecting method comprising:
a) receiving a plurality of source electricity values of a target electricity value, each of the source electricity values being obtained using a respective detector;
b) determining a threshold value and a weight value for each of the source electricity values;
c) selecting one of the source electricity values as a to-be-verified value;
d) selecting another one of the source electricity values as a to-be-compared value;
e) adding a predetermined value to the weight value of the to-be-verified value when an absolute value of a difference between the to-be-verified value and the to-be-compared value is smaller than an absolute value of a sum of the threshold values of the to-be-verified value and the to-be-compared value;
f) repeating step e) using yet another one of the source electricity values as the to-be-compared value until all of the source electricity values other than that selected as the to-be-verified value in step c) have been selected as the to-be-compared value;
g) repeating steps d) to f) using another one of the source electricity values as the to-be-verified value until all of the source electricity values have been selected as the to-be-verified value; and
h) determining a verified electricity value corresponding to the target electricity value based upon a quotient of a summation of products of each of the source electricity values and the weight value corresponding thereto, and a summation of the weight values of the source electricity values.

2. The electricity detecting method as claimed in claim 1, further comprising, between step g) and step h),
i) determining from the weight values if at least two of the detectors corresponding to at least two of the source electricity values have experienced breakdown, proceeding to step j) if the determination is affirmative, and proceeding to step h) if otherwise,
j) determining which ones of the detectors have experienced breakdown, and
k) repeating steps b) to g) while excluding the source electricity values and the weight values corresponding to the detectors that have experienced breakdown.

3. The electricity detecting method as claimed in claim 2, wherein the weight value determined in step b) has an initial value of 0, and the determination made in step i) is affirmative if the weight values are each non-zero and less than a product of one-half of a total number of the detectors and the predetermined value added in step e).

4. The electricity detecting method as claimed in claim 2, wherein the determination made in step i) is affirmative if each of the weight values is equal to an initial value thereof as determined in step b).

5. The electricity detecting method as claimed in claim 2, wherein step j) includes:
computing an average of previously determined verified electricity values;
computing a difference between each of the source electricity values and the average; and
for each of the source electricity values whose difference with the average is greater than the threshold value thereof, determining that the detector corresponding thereto has experienced breakdown.

6. The electricity detecting method as claimed in claim 1, wherein the threshold value determined in step b) ranges from 5% to 10% of the source electricity value.

7. The electricity detecting method as claimed in claim 1, wherein each of the detectors is one of a voltage detector and a current detector.

8. The electricity detecting method as claimed in claim 1, wherein each of the source electricity values is obtained through processing of a measuring electrical signal of the respective detector, the processing including amplifying the measuring electrical signal to result in an amplified electrical signal.

9. The electricity detecting method as claimed in claim 8, wherein the processing of the measuring electrical signal further includes adjusting level of the amplified electrical signal to result in an adjusted voltage signal, and converting the adjusted voltage signal into digital form to result in the source electricity value.

10. The electricity detecting method as claimed in claim 9, wherein the adjusted voltage signal ranges from 0V to 5V.

11. The electricity detecting method as claimed in claim 1, further comprising, between step a) and step b), excluding the source electricity value that exceeds a predetermined safety reference value such that the verified electricity value determined in step h) is not affected thereby.

12. An electricity detecting system comprising:
a detector module including a plurality of detectors, said detector module being operable to generate a plurality of source electricity values of a target electricity value, each of the source electricity values being obtained using a respective one of said detectors; and
a computing unit coupled to said detector module and receiving the source electricity values therefrom, said computing unit being configured to perform a method including the steps
a) determining a threshold value and a weight value for each of the source electricity values,
b) selecting one of the source electricity values as a to-be-verified value,
c) selecting another one of the source electricity values as a to-be-compared value,
d) adding a predetermined value to the weight value of the to-be-verified value when an absolute value of a difference between the to-be-verified value and the to-be-compared value is smaller than an absolute value of a sum of the threshold values of the to-be-verified value and the to-be-compared value,
e) repeating step d) using yet another one of the source electricity values as the to-be-compared value until all of the source electricity values other than that selected as the to-be-verified value in step b) have been selected as the to-be-compared value,
f) repeating steps c) to e) using another one of the source electricity values as the to-be-verified value until all of the source electricity values have been selected as the to-be-verified value, and
g) determining a verified electricity value corresponding to the target electricity value based upon a quotient of a summation of products of each of the source electricity values and the weight value corresponding thereto, and a summation of the weight values of the source electricity values.

13. The electricity detecting system as claimed in claim 12, wherein each of said detectors is one of a voltage detector and a current detector.

14. The electricity detecting system as claimed in claim 12, wherein each of said detectors outputs a measuring electrical signal from which the corresponding source electricity value is obtained, said detector module further including a plurality of amplifier circuits coupled respectively to said detectors for amplifying the measuring electrical signals to result in amplified electrical signals, respectively.

15. The electricity detecting system as claimed in claim 14, wherein said detector module further includes:
a plurality of adjusting circuits coupled respectively to said amplifier circuits for adjusting levels of the amplified electrical signals to result in adjusted voltage signals, respectively; and
an analog-to-digital converter coupled to said adjusting circuits for converting each of the adjusted voltage signals into digital form to result in the corresponding source electricity value.

16. The electricity detecting system as claimed in claim 15, wherein each of the adjusted voltage signals ranges from 0V to 5V.

17. The electricity detecting system as claimed in claim 12, wherein said detector module further includes a comparator circuit for indicating to said computing unit the source electricity value that exceeds a predetermined safety reference value, said computing unit being configured to exclude the source electricity value that exceeds the predetermined safety reference value from determination of the verified electricity value.

18. The electricity detecting system as claimed in claim 12, wherein the method further includes, between step f) and step g),
h) determining from the weight values if at least two of said detectors corresponding to at least two of the source electricity values have experienced breakdown, proceeding to step i) if the determination is affirmative, and proceeding to step g) if otherwise,
i) determining which ones of said detectors have experienced breakdown, and
k) repeating steps a) to f) while excluding the source electricity values and the weight values corresponding to said detectors that have experienced breakdown.

19. The electricity detecting system as claimed in claim 18, wherein step i) includes:
computing an average of previously determined verified electricity values;
computing a difference between each of the source electricity values and the average; and
for each of the source electricity values whose difference with the average is greater than the threshold value thereof, determining that said detector corresponding thereto has experienced breakdown.

20. The electricity detecting system as claimed in claim 12, wherein said processing unit is a single-chip microprocessor.
